(19) United States
(12) Patent Application Publication
(10) Pub. No.: US 2021/0180890 A1
(43) Pub. Date: Jun. 17, 2021

(54) HEAT DISSIPATION CONFIGURATION WITH WATER PUMP ASSEMBLY

(71) Applicant: SHENZHEN WAN JING HUA TECHNOLOGY CO., LTD., Shenzhen (CN)

(72) Inventor: Ming-Kun CHENG, Shenzhen (CN)

(21) Appl. No.: 16/713,634

(22) Filed: Dec. 13, 2019

(51) Int. Cl. F28F 27/02; F04D 3/00; F28D 1/04; F04D 13/02

(52) U.S. Cl. CPC F28F 27/02; F04D 13/02; F28D 1/04; F04D 3/00

(57) ABSTRACT

A heat dissipation configuration with water pump assembly includes a heat dissipation assembly, opposite first and second tanks respectively connected to an upper end and a lower end of the heat dissipation assembly, a water pump device mounted on the second tank and including a rotational impeller unit, and a joint assembly including an inlet joint connected to the second tank and a second pipe and an outlet joint connected to the water pump device and a first pipe. The first pipe and the second pipe extend to a heat generation unit. The water pump device and the joint assembly, situated at the lower end, combine to force liquid to move in a downstream direction and concurrently increase pressure of the liquid under the rotation of the impeller unit so that the liquid is continuously pumped from the second tank into the heat generation unit for dissipating heat quickly.

### BACKGROUND OF THE INVENTION

### 1. Field of the Invention

This invention relates to a heat dissipation device and relates particularly to the heat dissipation configuration having a water pump assembly.

### 2. Description of the Related Art

Generally, heat generation units of a computer such as CPU and chips generate heat while operating and need to cooperate with a heat dissipation device to disperse heat so that the heat generation units can operate normally. A conventional dissipation device usually uses fans to cause flowing air, thereby dissipating heat under the flow of air. However, the heat conduction of the air is not strong enough, so the effect of dissipating heat is limited. A water-cooling dissipation system has been created to replace the conventional fans. Referring to FIG. 1, a conventional water-cooling dissipation system includes a heat dissipation unit 11 in which a plurality of radiating fins are disposed, a pump 12, and a heat source 13. The heat dissipation unit 11 is connected to the pump 12 through a first pipe 14. The pump 12 is connected to the heat source 13 through a second pipe 15. The heat source 13 is connected to the heat dissipation unit 11 through a third pipe 16. The heat source 13 can be CPU or chips in a computer. Working fluid absorbs heat while passing through the heat source 13 to become endothermic fluid, and then the endothermic fluid enters the heat dissipation unit 11 through the third pipe 16 in order that the radiating fins of the heat dissipation unit 11 dissipate the heat in the fluid to decrease fluid temperature. The fluid with decreased fluid temperature is pumped into the pump 12 through the first pipe 14 under drawing force caused by operating the pump 12, and then the pump 12 adds pressure to pump the fluid into the heat source 13 through the second pipe 15. Accordingly, the endothermic process and the heat dissipating process of the fluid alternate for circulation whereby the heat source 13 is allowed to work normally. However, it is noted that the fluid becomes vaporized easily because of the heat during the circulation, so gas exits in the fluid. In this case, the fluid with gas or only the gas may be pumped into the heat source 13 when the pump 12 executes the drawing operation and adds pressure. In other words, the pump 12 cannot pump the fluid in a complete liquid state into the heat source 13, with the result that the amount of pumping fluid into the heat source 13 is decreased. This situation renders the fluid unable to absorb heat generated by operating the heat source 13 efficiently, which causes the heat source 13 to become overheated easily and fail to work normally. Thus, the conventional system still needs to be improved.

### SUMMARY OF THE INVENTION

The object of this invention is to provide a heat dissipation configuration with a water pump assembly which increases the pressure of liquid, provides increasing power for facilitating the continuous flow of the liquid, and increases the efficiency of heat dissipation.

The heat dissipation configuration with water pump assembly of this invention includes a heat dissipation assembly having opposite upper and lower ends, a first tank connected to the upper end of the heat dissipation assembly, a second tank connected to the lower end of the heat dissipation assembly, a water pump device mounted on the second tank, and a joint assembly. The heat dissipation assembly includes two fixing boards located opposite to each other, a plurality of radiating water tubes disposed between the fixing boards, and a plurality of radiating fins disposed between the radiating water tubes. An interior of the first tank communicates with an interior of the second tank through the radiating water tubes. The opposite first and second tanks are adapted to receive the flow of liquid. The second tank further has a through hole formed through a first side of the second tank. The water pump device includes a seat disposed on the first side of the second tank, a driving unit mounted in the seat, and an impeller unit connected to one end of the driving unit and located in a place relative to the through hole. The driving unit activates the rotation of the impeller unit. The impeller unit is immersed in the liquid for adding pressure to the liquid. The joint assembly includes an outlet joint and an inlet joint. The outlet joint is connected to the seat of the water pump device and communicates with an interior of the second tank. The inlet joint is connected to a second side of the second tank and communicates with the interior of the second tank. Between the outlet joint and a heat generation unit is disposed a first pipe connected to the outlet joint and extending to the heat generation unit. Between the inlet joint and the heat generation unit is disposed a second pipe connected to the inlet joint and extending to the heat generation unit. Accordingly, when the water pump device on which the outlet joint is disposed is directly situated at a lower position, liquid flows from the first tank into the second tank in a downstream direction for pumping the liquid into the heat generation unit continuously and quickly and also preventing the entry of gas into the liquid. Therefore, the heat absorbing effect of the liquid on the heat generation unit can be increased to prevent the heat generation unit from being overheated. Concurrently, the impeller unit rotates directly in the liquid so that the water pump device adds increasing pressure to the liquid to thereby attain continuous circulation of liquid and dissipate heat quickly.

Preferably, a filling port communicates with the interior of the second tank for supplementing additional liquid.

Preferably a sealing unit is disposed between the second tank and the seat for enhancing the sealing combination between the second tank and the water pump device.

Preferably, an auxiliary pump is connected to the inlet joint to provide the auxiliary drawing force beneficial to the pumping operation and the increasing pressure of the liquid.

### BRIEF DESCRIPTION OF THE DRAWINGS

FIG. 1 is a schematic view showing a conventional water-cooling dissipation system;

FIG. 2 is a perspective view showing a first preferred embodiment of this invention viewed from one visual angle;

FIG. 3 is a perspective view showing the first preferred embodiment of this invention viewed from another visual angle;

FIG. 4 is a partial enlarged view of FIG. 3;

FIG. 5 is a schematic view showing the use of the first preferred embodiment of this invention as a whole;

FIG. 6 is a schematic view showing the water pump device of the first preferred embodiment of this invention in use;

FIG. 6A is an enlarged cross-sectional view of the encircled portion A of FIG. 6;

FIG. 6B is an enlarged cross-sectional view of the encircled portion B of FIG. 6;

FIG. 6C is an enlarged cross-sectional view of the encircled portion C of FIG. 6; and

FIG. 7 is a schematic view showing a second preferred embodiment of this invention.

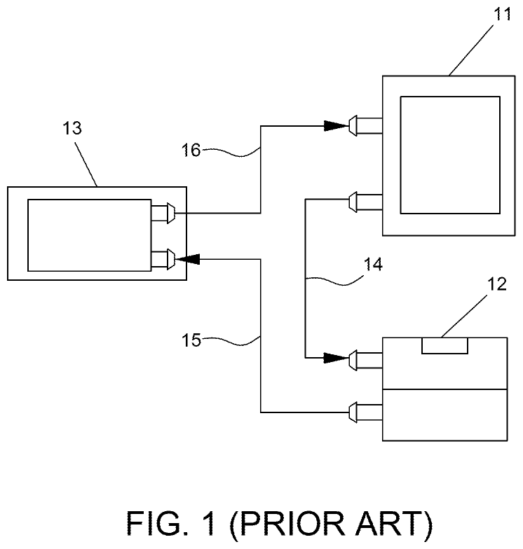

### DETAILED DESCRIPTION OF THE PREFERRED EMBODIMENTS

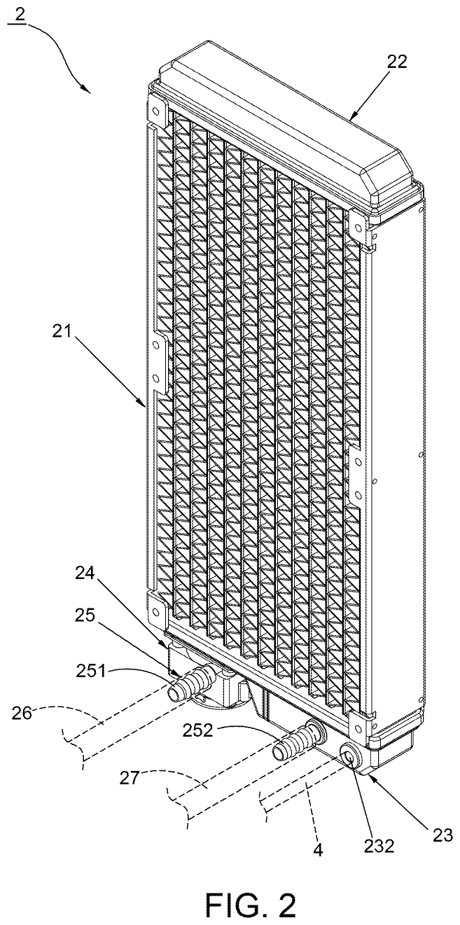

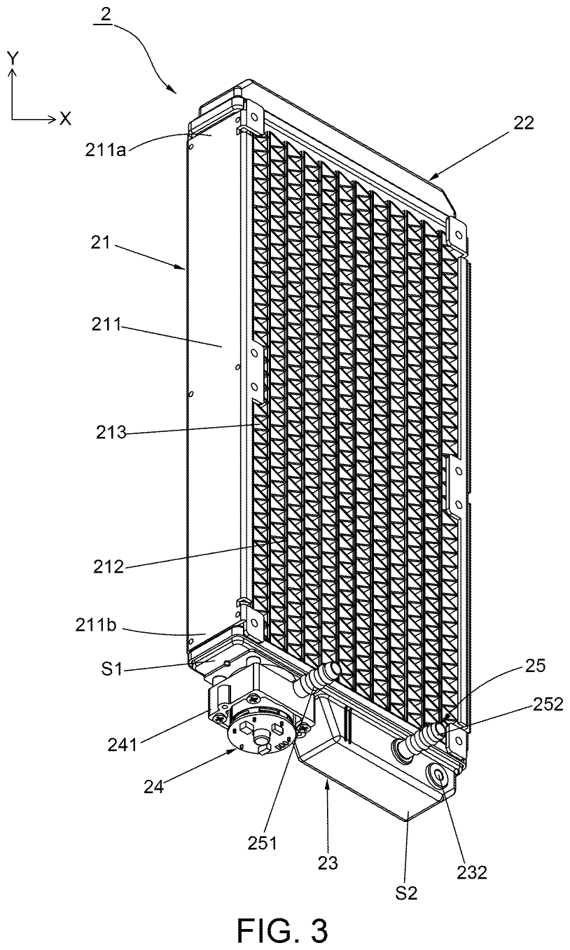

Referring to FIG. 2 and FIG. 3, a first preferred embodiment of a heat dissipation configuration 2 having a water pump assembly includes a heat dissipation assembly 21, opposite first and second tanks 22, 23, a water pump device 24 mounted on the second tank 23, and a joint assembly 25 in combination with the second tank 23 and the water pump device 24. The heat dissipation assembly 21 includes two fixing boards 211 and a plurality of radiating water tubes 212 and radiating fins 213. The two fixing boards 211 are located opposite to each other, and opposite upper and lower ends 211a, 211b are provided for the fixing boards 211 and thus are respectively defined as an upper location and a lower location of the heat dissipation assembly 21. The radiating water tubes 212 are disposed between the two fixing boards 212 and spaced from each other. The radiating fins 213 are disposed between the radiating water tubes 212. As for example shown in the figures, the radiating fins 213 can be evenly distributed along a longitudinal direction Y, and preferably, the radiating fins 213 can be formed into a bent plate to increase the area for dissipating heat among the space between the radiating water tubes 212.

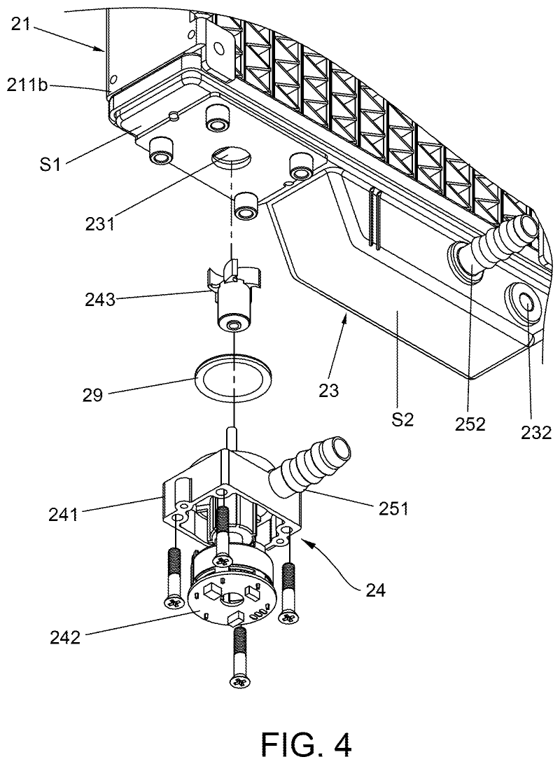

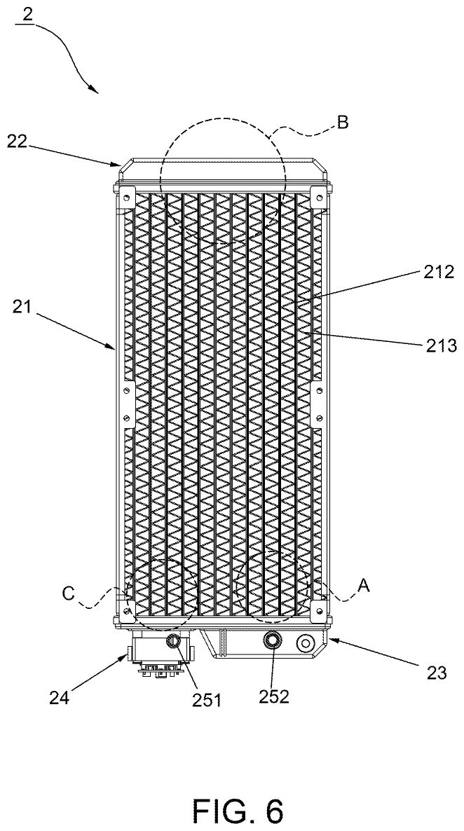

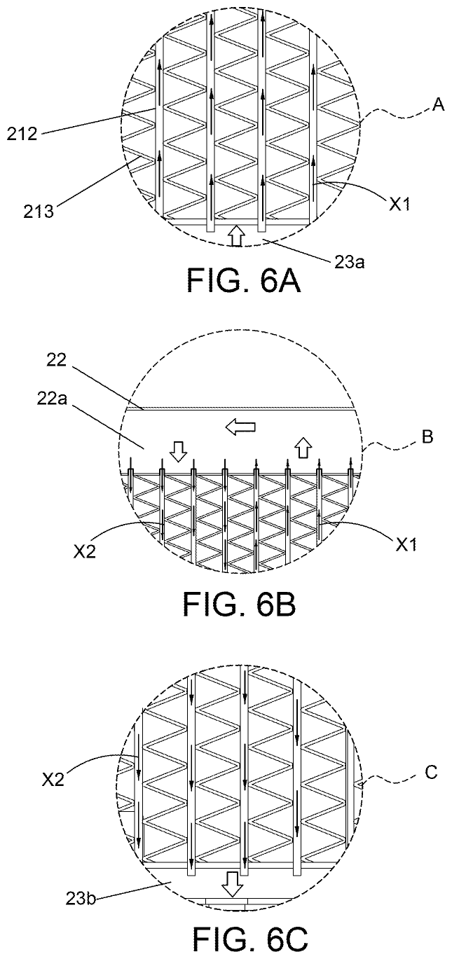

Also referring to FIGS. 6A to 6C, the first tank 22 is connected to the upper end 211a of the heat dissipation assembly 21, and an interior of the first tank 22 forms a first chamber 22a communicating with the radiating water tubes 212. The second tank 23 is connected to the lower end 211b of the heat dissipation assembly 21, and an interior of the second tank 23 forms an inlet chamber 23a and an outlet chamber 23b which communicate with the radiating water tubes 212 respectively. A through hole 231, shown in FIG. 4, is formed through a first side 81 of the second tank 23. The radiating water tubes 212 each extend from the first tank 22 to the second tank 23. Preferably, one end of each radiating water tube 212 is inserted into the interior of the first tank 22, and the other end thereof is inserted into the interior of the second tank 23. Accordingly, the radiating water tubes 212 extend between the first tank 22 and the second tank 23 so that the interior of the first tank 22 communicates with the interior of the second tank 23, including the inlet chamber 23a and the outlet chamber 23b, via the radiating water tubes 212, thereby allowing the liquid to flow in the heat dissipation assembly 2.

The water pump device 24 is mounted on the second tank 23. More specifically, as shown in FIG. 4, the water pump device 24 includes a seat 241 disposed on the first side 81 of the second tank 23, a driving unit 242 mounted in the seat 241, and an impeller unit 243 connected to one end of the driving unit 242. The impeller unit 243, preferably equipped with a plurality of vanes as shown, is driven by the driving unit 242 to become rotatable. When the seat 241, the driving unit 242, and the impeller unit 243 are assembled, the location of the impeller unit 243 is related to the place where the through hole 23 of the second tank 23 is formed to allow the impeller unit 243 to be partially or fully immersed in the liquid. For example, vanes of the impeller unit 243 may protrude from the through hole 243 and enter the interior of the second tank 23, such as the outlet chamber 23b. By the rotation of the impeller unit 243, the strength of pressure added to the liquid is increased to thereby promote the efficiency of pumping the liquid outwards. It is also preferable that a sealing unit 29 is disposed between the second tank 23 and the seat 241. The sealing unit 29 can be made of rubber or other elastic materials for attaining a good sealing combination between the second tank 23 and the water pump device 24.

The joint assembly 25 is disposed on the second tank 23 and the water pump device 24. More specifically, the joint assembly 25 includes an outlet joint 251 and an inlet joint 252. The outlet joint 251 is connected to the water pump device 24, i.e. the outlet joint 251 is disposed through the seat 241 of the water pump device 24 for communicating with the outlet chamber 23b of the second tank 23. The inlet joint 252 is connected to a second side S2 of the second tank 23, different from the first side 81, i.e. the inlet joint 252 is disposed through the second tank 23 for communicating with the inlet chamber 23a of the second tank 23. Accordingly, the outlet joint 251 disposed on the water pump device 24 and the inlet joint 252 disposed on the second tank 23 communicate with the interior of the second tank 23 at different locations. It is also noted that both of the inlet joint 252 and the outlet joint 251 are located at the lower position of the heat dissipation assembly 21, and the through hole 231 is formed between the outlet joint 251 and the outlet chamber 23b of the second tank 23 for outputting the liquid. The water pump device 24 is located at the lower end 211b, namely the lower position of the heat dissipation assembly 21, so the liquid flows in a downstream direction 82 and is forced to flow out of the outlet chamber 23b, as shown in FIG. 6C.

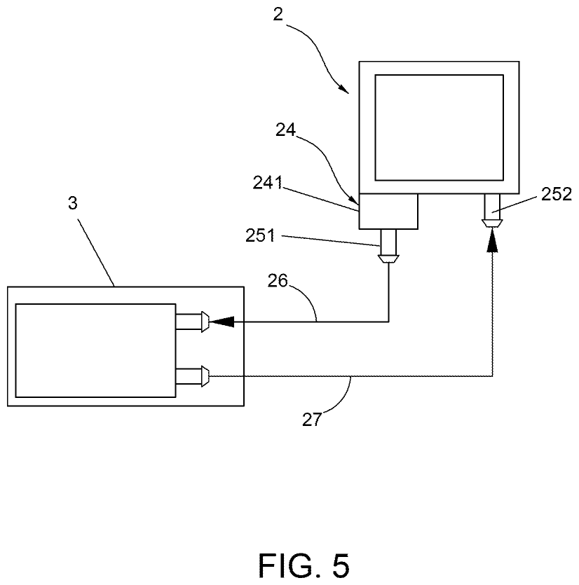

Referring to FIG. 2 through FIG. 5, a first pipe 26 is disposed between the outlet joint 251 and a heat generation unit 3. A second pipe 27 is disposed between the heat generation unit 3 and the inlet joint 252. Specifically, the first pipe 26 is connected to the outlet joint 251 and extends to the heat generation unit 3, and the second pipe 26 is connected to the inlet joint 252 and also extends to the heat generation unit 3. Further, it is possible that a filling port 232 is formed on the second tank 23 and communicating with the interior of the second tank 23. Preferably, the filling port 232 is disposed through the second side 82 of the second tank 23 and communicating with the inlet chamber 23a. This port 232 can be connected to an external pipe 4 so that additional liquid can be added from the port 232 into the heat dissipation configuration 2 for promoting the heat dissipation in case of overconsumption of original liquid within the heat dissipation configuration 2.

The operation of this invention is described with the aid of FIGS. 2 to 6. When liquid travelling through the heat generation unit 3 such as CPU of a computer and absorbing heat to become endothermic liquid enters from the inlet joint 252 into the inlet chamber 23a of the second tank 23 and thence into the radiating water tubes 212, heat in the liquid is distributed over the radiating fins 213 between the radiating water tubes 212. Because the radiating fins 213 formed in a bent shape has a larger area for being in contact with external flowing air, heat in the liquid is quickly dissipated because of the flowing air to attain the quick heat dissipation which helps decrease the liquid temperature. Further, as shown in FIGS. 6A to 6C, while flowing within the radiating water tubes 212, the liquid flows from the inlet chamber 23a towards the first chamber 22a of the first tank 22 in an upstream direction x1 and then flows from the first chamber 22a towards the outlet chamber 23b of the second tank 23 in a downstream direction X2. Then, the downstream-flowing liquid is outputted from the outlet joint 251 into the first pipe 26. Because the outlet chamber 23b of the second tank 23 is situated at the lower position of the heat dissipation assembly 21, liquid all crowds downwards because of the force of gravity. Further, when the liquid flows, gas caused by the vaporization of some liquid stays above the liquid because the specific gravity of the gas is less than that of the liquid. In other words, the gas does not go into the liquid. Meanwhile, because at least a portion of the impeller unit 243 such as its vanes can be immersed in the liquid, the rotation of the impeller unit 243 increases the contact area between the impeller unit 243 and the liquid and also adds pressure force to the liquid to increase the pressure of the liquid under the rotational force. This situation causes larger pumping force whereby the liquid subjected to the pressure force can be accelerated outwards away from the impeller unit 243 and be quickly forced out of the second tank 23. Thus, the water pump assembly 24 is disposed to increase the strength of pressurizing, thereby pumping the liquid into the heat generation unit 3 via the first pipe 26 quickly and continuously. It is noted that the crowded liquid is in a complete liquid state because of no entry of gas into the liquid, so the amount of pumping the liquid is increased to absorb a large amount of heat generated by the heat generation unit 3 quickly and prevent the heat generation unit 3 from overheating. Therefore, the heat generation unit 3 can work normally. After absorbing the heat, the endothermic liquid is then forced to travel in sequence through the second pipe 27, the inlet joint 252, the inlet chamber 23a of the second tank 23, and then back into the radiating water tubes 212 to execute the process of dissipating heat, as previously indicated. Thus, the water pump 24 operates to provide continuous power for the circulation of the liquid and to increase the efficiency of heat dissipation.

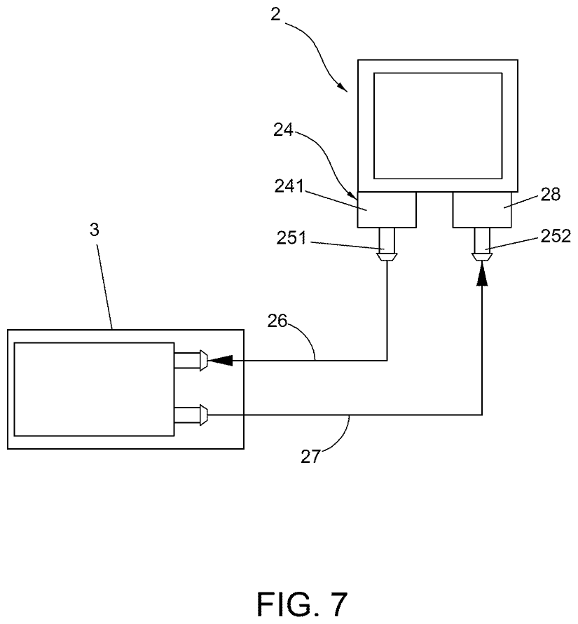

Referring to FIG. 7, a second preferred embodiment of a heat dissipation configuration 2 has the same elements and operations as the first preferred embodiment. The second preferred embodiment is characterized in that an auxiliary pump 28 is connected to the inlet joint 252, as briefly shown in the figure. By the auxiliary drawing force caused by the auxiliary pump 28, the pressure that water pump device 24 added to the liquid is largely increased when the endothermic liquid goes back into the heat dissipation configuration 2 via the second pipe 27. Thus, the quick heat dissipation is attained, and the liquid is continuously pumped into the heat generation unit 3 to prevent the heat generation unit 3 from overheating and operating abnormally.

To sum up, this invention takes advantage of the water pump device directly mounted on the second tank at the lower position of the heat dissipation assembly and the joint assembly connected to the water pump device and the second tank to force liquid to move from the first tank into the second tank in a downstream direction and to prevent the entry of gas into the liquid. Therefore, the heat in the liquid is dissipated quickly when the liquid is in the heat dissipation assembly, and concurrently the amount of pumping the liquid into the heat generation unit is increased so that the liquid absorbs a large amount of heat generated by the heat generation unit quickly. This invention also takes advantage of the rotation of the impeller unit of the water pump device immersed in the liquid to increase the pressure of the liquid, thereby attaining the continuous circulation of liquid and dissipating heat quickly.

While the embodiments are shown and described above, it is understood that further variations and modifications may be made without departing from the scope of this invention.

What is claimed is:

1. A heat dissipation configuration with water pump assembly comprising:
a heat dissipation assembly including two fixing boards located opposite to each other and having opposite upper and lower ends, a plurality of radiating water tubes disposed between said two fixing boards, and a plurality of radiating fins disposed between said plurality of radiating water tubes;
a first tank connected to said upper end of said two fixing boards and adapted to receive a flow of liquid;
a second tank connected to said lower end of said two fixing boards and adapted to receive said flow of said liquid, a through hole being formed through a first side of said second tank;
a water pump device mounted on said second tank, said water pump device including a seat disposed on said first side of said second tank, a driving unit mounted in said seat, and an impeller unit connected to one end of said driving unit, said driving unit being adapted to drive a rotation of said impeller unit, said impeller unit being located in a place relative to said through hole to allow said impeller unit to be immersed in said liquid; and
a joint assembly including an outlet joint connected to said seat and communicating with an interior of said second tank and an inlet joint connected to a second side of said second tank;
wherein a first pipe is connected to said outlet joint and extends to a heat generation unit, a second pipe being connected to said inlet joint and extending to said heat generation unit, an interior of said first tank communicating with said interior of said second tank through said plurality of radiating water tubes, said rotation of said impeller unit adding increasing pressure when said liquid flows from said second pipe, then said second tank and thence into said plurality of radiating water tubes to thereby force said liquid to flow to said interior of said first tank in an upstream direction and then flow from said interior of said first tank to said interior of said second tank in a downstream direction, said downstream-flowing liquid being pumped into said heat generation unit through said first pipe and then back to said second tank through said second pipe to enter said plurality of radiating water tubes for facilitating continuous circulation of said liquid and dissipating heat in said liquid quickly.

2. The heat dissipation configuration with water pump assembly according to claim 1, further comprising a filling port communicating with said interior of said second tank.

3. The heat dissipation configuration with water pump assembly according to claim 1, further comprising a sealing unit disposed between said second tank and said seat.

4. The heat dissipation configuration with water pump assembly according to claim 1, further comprising an auxiliary pump connected to said inlet joint.
